(19) United States
(12) Patent Application Publication
(10) Pub. No.: US 2026/0164978 A1
(43) Pub. Date: Jun. 11, 2026

(54) COLOR FILTER ARRANGEMENT STRUCTURE, DISPLAY PANEL AND DISPLAY DEVICE

(71) Applicants: Chengdu BOE Optoelectronics Technology Co., Ltd., Sichuan Province (CN); BOE Technology Group Co., Ltd., Beijing (CN)

(72) Inventors: Yanyang SHANG, Beijing (CN); Shuo LI, Beijing (CN); Zhenglong YAN, Beijing (CN); Zhu WANG, Beijing (CN)

(21) Appl. No.: 18/708,727

(22) PCT Filed: Feb. 27, 2023
(86) PCT No.: PCT/CN2023/078512

§ 371 Date: May 9, 2024

(51) Int. Cl. H10K 59/38; H10K 59/122

(52) U.S. Cl. CPC H10K 59/38; H10K 59/122

(57) ABSTRACT

A color filter arrangement structure, a display panel and a display device are provided. The color filter arrangement structure includes a first color filter, a second color filter and a third color filter which do not overlap with each other, and the first color filter covers an area between at least part of adjacent second color filters except a gap between the second color filter and the third color filter.

### CROSS REFERENCE TO RELATED APPLICATIONS

This application is a national phase entry under 35 U.S.C. § 371 of International Application No. PCT/CN2023/078512, filed on Feb. 27, 2023, the entire content of which is incorporated herein by reference.

### TECHNICAL FIELD

The disclosure relates to the field of display technology, in particular to a color filter arrangement structure, a display panel and a display device.

### BACKGROUND

Organic Light-Emitting Diode (OLED) display panel has many advantages such as self-illumination, ultra-thinness, fast response speed, high contrast, and wide viewing angle, and is a display panel that has received widespread attention.

In order to further improve the product performance of OLED display panels, the related art uses COE (Color Filter on Encapsulation) technology to add a color filter layer to the encapsulation layer (TFE) of OLED display panels, which does not require polarizers (POL), which can effectively improve display brightness, reduce overall thickness, and improve display color gamut.

### SUMMARY

Some embodiments of the disclosure provide a color filter arrangement structure, a display panel and a display device, specifically as following.

An embodiment of the disclosure provides a color filter arrangement structure, including: a first color filter, a second color filter and a third color filter which do not overlap with each other, and the first color filter covers an area between at least part of adjacent second color filters except a gap between the second color filter and the third color filter.

In some embodiments, a shape of the first color filter is a polygon, a corner of the polygon is a first circular arc that is convex to a side away from a center of the polygon, and at least one edge of the polygon is concave toward the center of the polygon.

In some embodiments, a shape of the second color filter includes a circle or an oval, and a shape of the third color filter includes a circle or an oval. The second color filter and the third color filter are alternately arranged at a side of each edge of the first color filter.

In some embodiments, the color filter arrangement structure includes a first area, each first color filter in the first area covers an area except the gap between the second color filter and the third color filter, and each edge of each first color filter in the first area is concave toward the center of the polygon.

In some embodiments, concave surfaces corresponding to the second color filter and the third color filter are second circular arcs, a second circular arc corresponding to the second color filter is the same as a shape of an edge of the second color filter adjacent to the second circular arc, and a second circular arc corresponding to a third color filter is the same as a shape of an edge of the third color filter adjacent to the second circular arc.

In some embodiments, the color filter arrangement structure further includes a second area, and the first color filter located in the second area covers the area between the at least part of the adjacent second color filters except the gap between the second color filter and the third color filter; the second area includes a plurality of light-transmitting holes, and the light-transmitting holes are located in areas of the gap between adjacent second color filters that are not covered by the first color filter.

In some embodiments, each edge of the first color filter in the second area is concave towards the center of the polygon, a concave surface corresponding to the light-transmitting hole is a third circular arc, a shape of each light-transmitting hole is a special-shaped polygon, and a figure of the light-transmitting hole is roughly complementary to a figure of concave surface adjacent to the light-transmitting hole.

Correspondingly, an embodiment of the disclosure further provides a display panel, including: a base substrate; a pixel defining layer at a side of the base substrate, and the pixel defining layer including a plurality of first openings; an encapsulation layer at a side of the pixel defining layer away from the base substrate; a black matrix layer at a side of the encapsulation layer away from the base substrate, and the black matrix layer including a plurality of second openings corresponding to the first openings in one-to-one manner; a color filter layer at a side of the black matrix layer away from the base substrate, and the color filter layer including a first color filter, a second color filter and a third color filter corresponding to the second openings in one-to-one manner, and the first color filter, the second color filter and the third color filter not overlapping with each other. The first color filter covers an area between at least part of adjacent second color filters except a gap between the second color filter and the third color filter.

In some embodiments, an area of the first color filter is greater than an area of the third color filter, and the area of the third color filter is greater than an area of the second color filter.

In some embodiments, a periphery of the first color filter is provided with the second color filter and the third color filter arranged alternately around the first color filter.

In some embodiments, a shape of the second color filter includes a circle or an oval, and a shape of the third color filter includes a circle or an oval.

In some embodiments, a shape of the first color filter is a polygon, and the second color filter and the third color filter arranged alternately around the first color filter are respectively located at a side of each edge of the polygon.

In some embodiments, a corner of the polygon is a first circular arc that is convex to a side away from a center of the polygon.

In some embodiments, a radius of the first arc ranges from 3.5 μm to 4 μm.

In some embodiments, at least one edge of the polygon is concave toward the center of the polygon.

In some embodiments, concave surfaces corresponding to the second color filter and the third color filter are second circular arcs, a second circular arc corresponding to the second color filter is the same as a shape of an edge of the second color filter adjacent to the second circular arc, and a second circular arc corresponding to the third color filter is the same as a shape of an edge of the third color filter adjacent to the second circular arc.

In some embodiments, a width of a gap between the first color filter and the second color filter which are adjacent, ranges from 1 μm to 1.5 μm; a width of a gap between the first color filter and the third color filter which are adjacent, ranges from 1 μm to 1.5 μm, and a width of a gap between the second color filter and the third color filter which are adjacent, is greater than or equal to 1 μm.

In some embodiments, the display panel includes a conventional display area, and the first color filter in the conventional display area covers an area except the gap between the second color filter and the third color filter.

In some embodiments, each edge of the first color filter in the conventional display area is concave toward the center of the polygon.

In some embodiments, the first color filter in the conventional display area is a central symmetrical figure.

In some embodiments, the display panel further including a light-transmitting display area, and the first color filter in the light-transmitting display area covers the area between the at least part of adjacent second color filters except the gap between the second color filter and the third color filter. The light-transmitting display area includes a plurality of light-transmitting holes, and the light-transmitting holes are located in an area not covered by the first color filter, of the gap between adjacent second color filters.

In some embodiments, each edge of the first color filter in the light-transmitting display area is concave toward the center of the polygon.

In some embodiments, a concave surface corresponding to the light-transmitting holes is a third circular arc, a shape of the light-transmitting hole is a special-shaped polygon, and a figure of the light-transmitting hole is roughly complementary to a figure of concave surface adjacent to the light-transmitting hole.

In some embodiments, in the light-transmitting display area, the first color filter includes a long axis extending along a first direction and a short axis extending along a second direction, and the light-transmitting holes are arranged at two ends of the short axis; and the first direction intersects the second direction. Or, in the light-transmitting display area, the first color filter includes a short axis extending along a first direction and a long axis extending along a second direction, and the light-transmitting holes are arranged at two ends of the short axis. Or, in the light-transmitting display area, a part of the first color filters include a long axis extending along a first direction and a short axis extending along a second direction, the other part of the first color filters include a short axis extending along the first direction and a long axis extending along the second direction, and the light-transmitting holes are located at two ends of the short axis.

In some embodiments, a width of a gap between the light-transmitting hole and the first color filter is greater than or equal to 1 μm, and a width of a gap between the light-transmitting hole and the third color filter is greater than or equal to 1 μm.

In some embodiments, an area of the second opening is greater than an area of the first opening.

In some embodiments, an area of the first color filter is greater than an area of a corresponding second opening, an area of the second color filter is greater than an area of a corresponding second opening, and an area of the third color filter is greater than an area of a corresponding second opening.

In some embodiments, a shape of the first opening includes a circle or an oval, and a shape of the second opening includes a circle or an oval.

In some embodiments, the first color filter is a red color filter, the second color filter is a green color filter, and the third color filter is a blue color filter.

Correspondingly, an embodiment of the disclosure further provides a display device, including the display panel as described in above embodiments of the disclosure.

### BRIEF DESCRIPTION OF FIGURES

FIG. 1 is a schematic planar diagram of a display panel according to embodiments of the disclosure.

FIG. 2 is a cross-sectional view along a direction CC′ in FIG. 3 and FIG. 4.

FIG. 3 is a schematic planar diagram of an area in the dashed box BB in FIG. 1.

FIG. 4 is a schematic planar diagram of the area A2 in FIG. 1.

FIG. 5 is an enlarged view of a part of FIG. 3.

FIG. 6 is an enlarged view of a part of FIG. 4.

FIG. 7 is a partially enlarged view of the area A2 in FIG. 1.

FIG. 8 is another schematic planar diagram of the area A2 in FIG. 1.

FIG. 9 is another schematic planar diagram in the area A2 in FIG. 1.

FIG. 10 is a schematic diagram of a display device according to embodiments of the disclosure.

### DETAILED DESCRIPTION

In order to make the purpose, technical solution and advantages of the embodiments of the disclosure clearer, the technical solutions of the embodiments of the disclosure will be clearly and completely described below in conjunction with the accompanying drawings of the embodiments of the disclosure. Obviously, the embodiments described are some embodiments of the disclosure, not all embodiments. And in the absence of conflict, the embodiments in the disclosure and the features in the embodiments may be combined with each other. Based on the embodiments of the disclosure described, all other embodiments obtained by a person skilled in the art without creative labor are within the scope of protection of the disclosure.

Unless otherwise defined, the technical or scientific terms used in this disclosure shall have the ordinary meaning understood by persons with general skills in the field to which this disclosure belongs. Words similar to the words “include” or “comprise” as used in this disclosure are intended to mean that the element or thing that precedes the word includes the element or thing listed after the word and its equivalent, without excluding other elements or objects. Similar terms such as “connection” or “connected” are not limited to physical or mechanical connections, but may include electrical connections, whether direct or indirect. “Inside”, “Outside”, “Up”, “Down”, etc., are only used to indicate a relative positional relationship, and when the absolute position of the described object changes, the relative positional relationship may also change accordingly.

It should be noted that the dimensions and shapes of the figures in the drawings do not reflect the true proportions, and are intended to illustrate the contents of this disclosure. The same or similar designation at all times indicates the same or similar element or component with the same or similar function.

According to the research of the inventor in this case, in the related art, while the OLED display panel with COE structure is in the dark state, that is, when the screen is off, when the external ambient light is reflected by the internal structure of the OLED display panel and emits from the color filter film, the reflected light hue deviation and the obvious color separation phenomenon on the screen lead to a problem that the screen cannot display a pure black picture in the dark state.

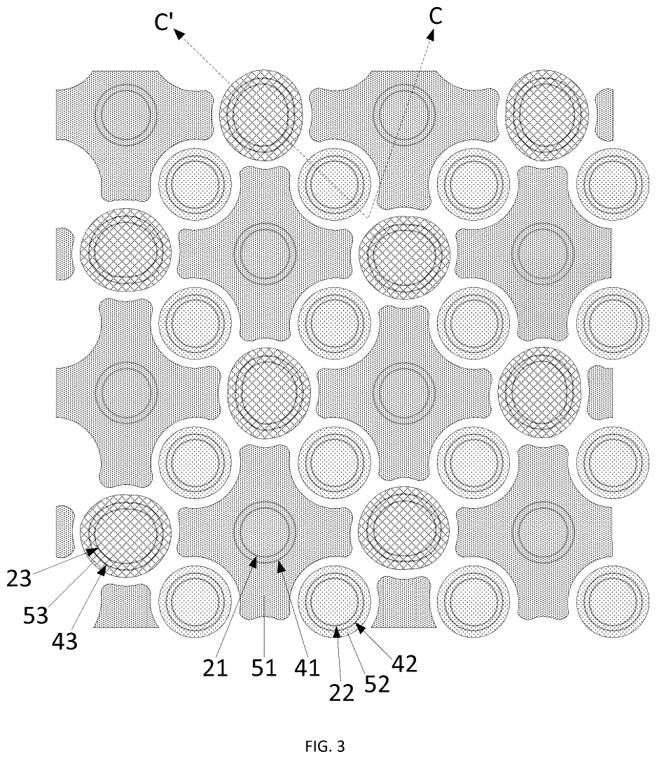

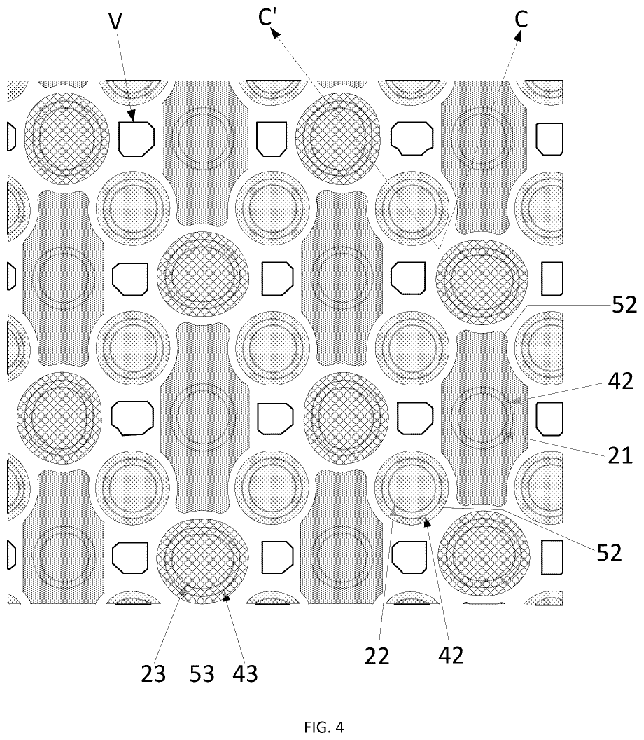

In view of this, in order to solve above technical issue, an embodiment of the disclosure provides a color filter arrangement structure, as shown in FIG. 3 and FIG. 4, including a first color filter 51, a second color filter 52 and a third color filter 53 that do not overlap each other. The first color filter 51 covers an area between at least part of adjacent second color filters 52 except a gap between the second color filter 52 and the third color filter 53.

In the above-mentioned color filter arrangement structure provided in the embodiment of the disclosure, the first color filters 51, the second color filter 52 and the third color filter 53 that do not overlap each other are arranged, and the first color filter 51 covers the area between at least part of the adjacent second color filters 52 except the gap between the second color filter 52 and the third color filter 53, so that when the color filter arrangement structure is the color filter layer of the display panel with the COE structure of high resolution, the first color filter 51, the second color filter 52 and the third color filter 53 do not overlap with each other, and the area filled with the first color filter 51 is increased as much as possible, the dark hue of the product can be optimized, and the green reflected light is reduced when the display panel is off, so that the screen is closer to black, and the problem that the screen cannot display a pure black picture in the dark state due to the hue deviation of the reflected light in the related art can be solved.

In the specific embodiment, in the above-mentioned color filter arrangement structure provided in the present embodiment, as shown in FIG. 3 and FIG. 4, the shape of the first color filter 51 can be a polygon, and a corner of the polygon is a first circular arc that is convex to a side that is far away from a center of the polygon, so that the arc-shaped corner design of the first color filter 51 can weaken the abrupt change in size at a sharp corner, weaken the diffraction effect of the reflected light produced by the external ambient light after passing through the display panel, thereby weakening the color separation phenomenon. At least one edge of the polygon is concave toward the center of the polygon. Optionally, as shown in FIG. 3, each edge of the polygon (first color filter 51) is a second circular arc that is concave to the center position of the polygon. As shown in FIG. 4, six edges of the polygon (first color filter 51) are the second circular arcs concave to the center of the polygon. In this way, compared with each corner of the color filter in the conventional display panel being sharp corner, the arc-shaped corner design in the embodiments of the disclosure can weaken the abrupt change in size at the sharp corner, and weaken the diffraction effect of the reflected light produced by the external ambient light after passing through the display panel, thereby weakening the color separation phenomenon.

In the specific embodiment, in the above-mentioned color filter arrangement structure provided in the embodiment of the disclosure, as shown in FIG. 3 and FIG. 4, the shape of the second color filter 52 includes a circle or an oval, and the shape of the third color filter 53 includes a circle or an oval. The embodiment of the disclosure takes the shape of the second color filter 52 as a circle, the shape of the third color filter 53 is an oval as an example, the design that the circular or oval color filter, compared with the design that the color filter having a sharp angle at the corner position in the conventional display panel, making the second color filter 52 and the third color filter 53 in the embodiment of the disclosure circle or oval, can weaken the abrupt change in size at the sharp corners to weaken the diffraction effect of the reflected light generated by the external ambient light through the display panel, thereby weakening the color separation phenomenon.

The second color filter 52 and the third color filter 53 are alternately arranged at each edge of the first color filter 51, so that the first color filter 51, the second color filter 52 and the third color filter 53 can be closely arranged, allowing a high-resolution of the display panel with COE structure.

In the specific embodiment, in the above-mentioned color filter arrangement structure provided in the embodiment of the disclosure, the color filter arrangement structure may include a first area (corresponding to the conventional display area of the display panel). As shown in FIG. 3, FIG. 3 shows a part of the color filter structure in the first area, and each first color filter 51 in the first area covers the area except the gap between the second color filter 52 and the third color filter 53, so that on the one hand, it can be avoided the overlap of the first color filter 51 and the second color filter 52 and the third color filter 53 when making the first color filter 51 for the current high-resolution display panel, because the length of the gap between the second color filter 52 and the third color filter 53 cannot satisfy the filling of the first color filter 51, so the first color filter 51 of the disclosure embodiment does not cover this gap. The reflected stray light appearing due to color separation in the dark state can be avoid. On the other hand, the production area of the first color filter 51 can be improved, so that the hue of the display panel in the dark state is better. Further, each edge of each first color filter 51 in the first area is concave toward the center of the polygon. Compared with that each corner of the color filter in the conventional display panel is sharp corner, the arc-shaped corner design in the embodiment of the disclosure can weaken the abrupt change in size at the sharp corner, and the diffraction effect of the reflected light produced by the external ambient light after passing through the conventional display area of the display panel can be weakened, thereby reducing the phenomenon of color separation in the conventional display area.

In the specific embodiment, in the above-mentioned color filter arrangement structure provided in the embodiment of the disclosure, as shown in FIG. 3, the surface of the concave part (each edge of the first color filter 51) corresponding to the second color filter 52 and the third color filter 53 is a second circular arc. The second circular arc can be the same as the shape of the edge of the second color filter 52 adjacent to the second circular arc, and the second circular arc can be the same as the shape of the edge of the third color filter 53 adjacent to the second circular arc, so that a pattern of the first color filter 51 is complementary to the patterns of the second color filter 52 and the third color filter 53.

In the specific embodiment, in the above-mentioned color filter arrangement structure provided in the embodiments of the disclosure, the color filter arrangement structure further includes a second area (corresponding to a light-transmitting display area of the display panel). As shown in FIG. 4, FIG. 4 shows a part of the color filter structure in the second area, and the first color filter 51 located in the second area covers at least a part of the area between adjacent second color filters 52 except the gap between the second color filter 52 and the third color filter 53.

The second area includes a plurality of light-transmitting holes V. The light-transmitting hole V is located in the area of the gap between adjacent second color filters 52 that is not covered by the first color filter 51. Because the pixel definition layer and the black matrix layer in the display panel cannot transmit light, a hole can be made on the pixel definition layer and the black matrix layer in the area of the gap between the adjacent second color filters that is not covered by the first color filter, so as to realize the light transmission in the hole area.

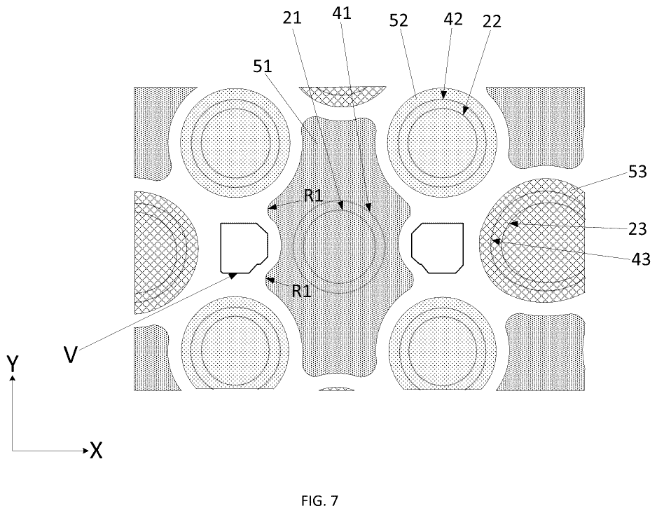

In the specific embodiment, in the above-mentioned color filter arrangement structure provided in the present embodiment, as shown in FIG. 7, each edge of the first color filter 51 in the second area is concave towards the center of the polygon, so that the diffraction effect of the reflected light produced by the external ambient light after passing through the transmitting display area A2 of the display panel can be weakened, thereby weakening the color separation phenomenon in the transmitting display area A2. The concave surface corresponding to the light-transmitting hole V is a third circular arc. The shape of the light-transmitting hole V can be a special-shaped polygon, and the graphic of the light-transmitting hole V is roughly complementary to the graphic of the adjacent concave. In this way, the design of the light-transmitting hole V with special-shaped polygonal structure can increase the area of the light-transmitting hole V, thereby increasing the transmittance of the transmitting display area A2 and improving the sensitivity of the ambient light adjustment sensor.

In the specific embodiment, in the above-mentioned color filter arrangement structure provided in the embodiment of the disclosure, as shown in FIG. 3 and FIG. 4, the first color filter can be a red color filter (R), the second color filter can be a green color filter (G), and the third color filter can be a blue color filter (B).

It should be noted that the detailed descriptions of the first color filter, the second color filter, the third color filter and the light-transmitting hole can be seen in the description of the display panels below.

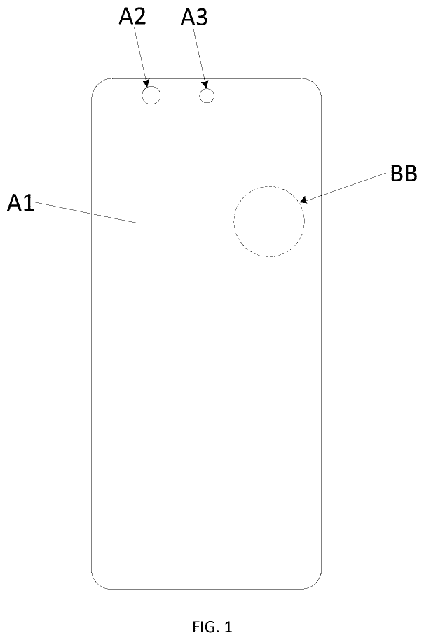

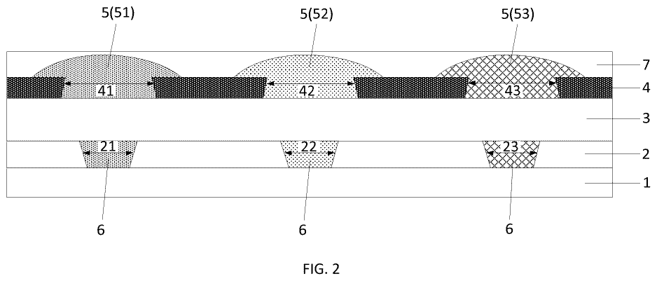

Based on the same invention conception, the embodiment of the disclosure further provides a display panel, as shown in FIG. 1 to FIG. 4. Here FIG. 1 is a schematic planar diagram of the display panel, FIG. 2 is a cross-section view along the direction CC′ in FIG. 3 and FIG. 4, FIG. 3 is a schematic planar diagram of the area in the dashed line box BB in FIG. 1, and FIG. 4 is a schematic planar diagram of the area A2 in FIG. 1. The display panel includes:
a base substrate 1, specifically, the base substrate 1 may be a rigid substrate or a flexible substrate, the rigid substrate may be but not limited to glass, etc., and the flexible substrate may be but not limited to polyethylene terephthalate, ethylene terephthalate, polyimide, etc.;
a pixel defining layer 2 at a side of the base substrate 1, having a plurality of first openings (21, 22, and 23);
an encapsulation layer 3 at a side of the pixel defining layer 2 away from the base substrate 1; specifically, the encapsulation layer 3 may be a thin-film encapsulation layer, which may specifically include a first inorganic encapsulation layer, an organic encapsulation layer and a second inorganic encapsulation layer that are stacked in sequence;
a black matrix layer 4 at a side of the encapsulation layer 3 away from the base substrate 1, where the black matrix layer 4 has a plurality of second openings (41, 42 and 43) arranged one-to-one with the first openings (21, 22 and 23);
a color filter layer 5 at a side of the black matrix layer 4 away from the base substrate 1, where the color filter layer 5 has a first color filter 51, a second color filter 52 and a third color filter 53 corresponding to the second opening (41, 42 and 43) in an one-to-one manner, the first color filter 51, the second color filter 52 and the third color filter 53 do not overlap each other. Specifically, the first opening 21, the second opening 41 and the first color filter 51 are correspondingly arranged, the first opening 22, the second opening 42 and the second color filter 52 are correspondingly arranged, and the first opening 23, and the second opening 43 and the third color filter 53 are correspondingly arranged. That is, the first opening 21 is configured to emit red light, the first opening 22 is configured to emit green light, and the first opening 23 is configured to emit blue light.

The first color filter 51 covers the area between at least part of adjacent second color filters 52 except the gap between the second color filter 52 and the third color filter 53.

The embodiment of the disclosure provides the above-mentioned display panel, by setting up the first color filters 51, the second color filter 52 and the third color filter 53 that do not overlap with each other, and the first color filter 51 covers the area between at least part of the adjacent second color filters 52 except the gap between the second color filter 52 and the third color filter 53, so that for the high-resolution display panel, the first color filter 51 and the second color filter 52 and the third color filter 53 do not overlap with each other, and the filling area of the first color filter 51 is improved as much as possible, the dark hue of the product can be optimized, and the green reflected light is reduced when the display panel is in the off state, so that the screen is closer to black, and further the problem that the screen cannot display a pure black picture in the dark state due to the hue deviation of the reflected light in the related art can be solved.

In the specific embodiment, in the above-mentioned display panel provided in the embodiments of the disclosure, as shown in FIG. 2 to FIG. 4, the first color filter 51 can be a red color filter (R), the second color filter 52 can be a green color filter (G), and the third color filter 53 can be a blue color filter (B).

In the specific embodiment, the display panel provided in the embodiment of the disclosure, as shown in FIG. 2, further includes a plurality of light-emitting devices. Each light-emitting device includes an anode (not shown), a light-emitting layer 6 and a cathode (not shown) arranged in a stack. Each anode is formed before the pixel defining layer 2. The first openings of the pixel defining layer 2 (21, 22 and 23) expose the anode, and the pixel defining layer 2 covers the edge area of the anode. Each light-emitting layer 6 is arranged at the corresponding first opening (21, 22 and 23). For example, a light-emitting layer 6 emitting red light is arranged in the first opening 21, a light-emitting layer 6 emitting green light is arranged in the first opening 22, and a light-emitting layer 6 emitting blue light is arranged in the first opening 23. The cathode can be a structure throughout the surface.

In the specific embodiment, the display panel provided in the embodiments of the disclosure, as shown in 2, further includes a thin-film transistor array layer (not shown) between the base substrate 1 and the pixel delimiting layer 2. The thin-film transistor array layer may include an active layer, a gate insulation layer, a gate layer, a source-drain conductive layer and a planarization layer. A drain of the thin-film transistor array layer is electrically connected with the anode, and the light-emitting device is driven to emit light through the thin-film transistor.

It should be noted that the light-emitting devices in the embodiment of the disclosure may include: OLED devices or quantum dot light-emitting diodes (QLED) devices, etc., and no specific restrictions are made on this.

In the specific embodiment, the display panel provided in the embodiment of the disclosure, as shown in 2, further includes a protective layer 7 at a side of the color filter layer 5 away from the base substrate 1. The protective layer 7 may be an optical adhesive layer to protect the color filter layer 5 and the black matrix layer 4.

In the specific embodiment, in the display panel provided in the embodiment of the disclosure, as shown in 2, a cover plate (not shown in the figure) or a covering film layer (not shown in the figure) is further arranged at a side of the protective layer 7 away from the color filter layer 5. The cover plate can be a glass cover.

It is understood that, as shown in FIG. 2, the display panel in the embodiment of the disclosure may not include a circular polarizer. By using the black matrix layer 4 and the color filter layer 5 provided in the embodiment of the disclosure, at the position where it is necessary to display, that is, the position where each light-emitting layer 6 is located, the light emitted by the light-emitting layer 6 passes through a second opening (41, 42 and 43) to exit, which does not affect the display. The position other than the light-emitting layer 6 can be blocked by the black matrix layer 4, so that the external ambient light cannot enter, serving as a circular polarizer to prevent the reflection of external light.

In the specific embodiment, as shown in FIG. 2, the first color filter 51, the second color filter 52 and the third color filter 53 can not only filter the emergent light, improving the color purity of the emergent light, but also can filter the external light, reducing the ambient light entering the display panel, and further reducing the reflection of the display panel to the ambient light, finally improving the user experience.

In the specific embodiment, the display panel of the COE structure generally has the strongest green reflected light and the weakest red reflected light in the dark state, making the screen unable to display a pure black picture in the dark state, so in the above-mentioned display panel provided in the embodiment of the disclosure, as shown in FIG. 3 and FIG. 4, the area of the first color filter 51 is greater than the area of the third color filter 53, and the area of the third color filter 53 is greater than the area of the second color filter 52. In this way, when the display panel is off, the green reflected light can be reduced, making the screen closer to a pure black picture.

In the specific embodiment, in the display panel provided in the embodiment of the disclosure, as shown in FIG. 3 and FIG. 4, the first color filter 51 is surrounded by the second color filter 52 and the third color filter 53 arranged alternately. Specifically, the shape of the first color filter 51 can be polygonal, and the second color filter 52 and the third color filter 53 that are alternately arranged around the first color filter 51 are respectively positioned at one edge of the polygon, so that the first color filter 51, the second color filter 52 and the third color filter 53 can be closely arranged, realizing a high-resolution display panel.

Specifically, in the embodiments of the disclosure, the shape of the body of the first color filter 51 approximately being an octagon is taken as an example for illustration, which is of course not limited to this.

In the specific embodiment, in the display panel provided in the embodiments of the disclosure, the shape of the second color filter may include a circle or an oval, and the shape of the third color filter may include a circle or an oval. Optionally, as shown in FIG. 3 and FIG. 4, the embodiment of the disclosure takes the shape of the second color filter as a circle and the shape of the third color filter as an oval. Compared with the color filter of sharp corner in the conventional display panel, the second color filter and the third color filter in the embodiment of the disclosure are circular or oval, which can weaken the abrupt change in size at the sharp corners, weaken the diffraction effect of the reflected light produced by the external ambient light after passing through the display panel, thereby weakening the color separation phenomenon.

It should be noted that the shape of the second color filter and the third color filter disclosed in the embodiment of the disclosure is circle or oval, indicating an approximation of a circle or an oval. It can be understood that due to reasons such as the production process, the shape of the second color filter and the third color filter produced is not necessarily a standard circle or an oval, and there can be a certain error.

In the specific embodiment, in the above-mentioned display panel provided in the embodiment of the disclosure, as shown in FIG. 3 and FIG. 4, the corner of the polygon (first color filter 51) is the first circular arc that is convex to the side away from the center of the polygon, making the arc-shaped corner design of the first color filter 51. Compared with the sharp corner of the color filter in the conventional display panel, the arc-shaped corner design in the embodiment of the disclosure can weaken the abrupt change in size at the sharp corner, weaken the diffraction effect of the reflected light produced by the external ambient light after passing through the display panel, thereby weakening the color separation phenomenon.

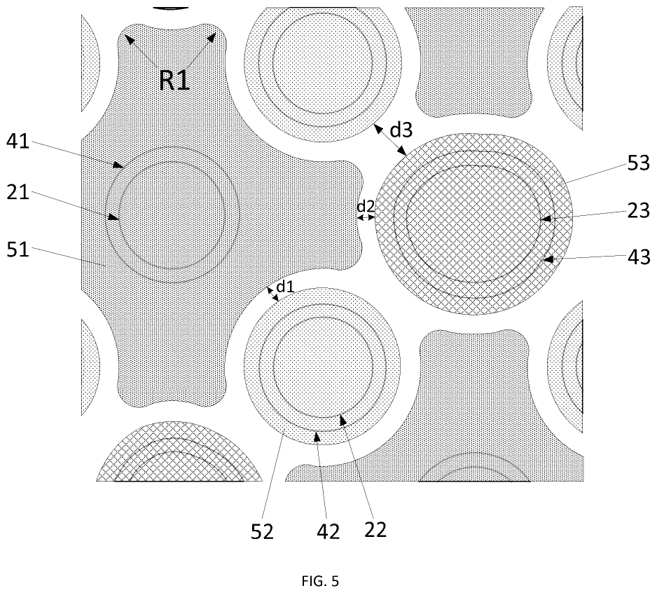

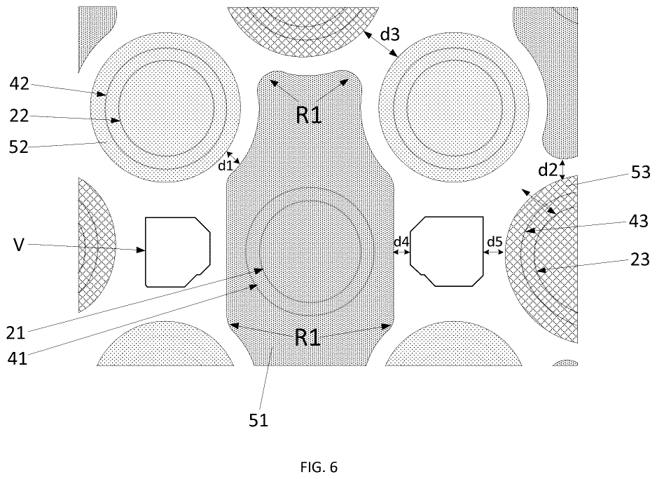

In the specific embodiment, in the above-mentioned display panel provided in the embodiment of the disclosure, as shown in FIG. 5 and FIG. 6, FIG. 5 is an partially enlarged view of FIG. 3, and FIG. 6 is a partially enlarged view of FIG. 4. The radius R1 of the first circular arc can range from 3.5 μm to 4 μm, ensuring that the pattern of the first color filter 51 can be stably exposed during the critical dimension (CD) process, so that the process stability can be improved to reduce the difference between pieces.

In the specific embodiment, in the above-mentioned display panel provided in the embodiment of the disclosure, as shown in FIG. 3 to FIG. 6, at least one edge of the polygon (first color filter 51) is concave toward the center of the polygon. Optionally, as shown in FIG. 3 and FIG. 5, each edge of the polygon (first color filter 51) is concave toward the center position of the polygon. As shown in FIG. 4 and FIG. 6, six edges of the polygon (first color filter 51) are concave toward the center position of the polygon. In this way, compared with the edges of the color filter in the conventional display panel are straight lines, the concave design of each edge in the embodiment of the disclosure can weaken the diffraction effect of the reflected light produced by the external ambient light after passing through the display panel, thereby weakening the color separation phenomenon.

In the specific embodiment, in the above-mentioned display panel provided in the embodiment of the disclosure, as shown in FIG. 3 to FIG. 6, the concave surface of the first color filter corresponding to the second color filter 52 and the third color filter 53 can be a second circular arc. The shape of the edge of the second circular arc can be the same as the shape of the edge of the second color filter 52 adjacent to the second circular arc. The edge of the shape of the second circular arc can be the same as the shape of the edge of the third color filter 53 adjacent to the second circular arc, so that the pattern of the first color filter 51 is complementary to the patterns of the second color filter 52 and the third color filter 53.

In the specific embodiment, in the above-mentioned display panel provided in the embodiment of the disclosure, as shown in FIG. 5 and FIG. 6, the width d1 of the gap between the adjacent first color filter 51 and the second color filter 52 ranges from 1 μm to 1.5 μm, the width d2 of the gap between the adjacent first color filter 51 and the third color filter 53 ranges from 1 μm to 1.5 μm, and the width d3 of the gap between the adjacent second color filter 52 and the third color filter 53 is greater than or equal to 1 μm. On the one hand, this can prevent overlapping between the first color filter 51, the second color filter 52 and the third color filter 53, and on the other hand, the area filled with the first color filter 51 can be improved, so that the display panel is better in the dark state.

In the specific embodiment, in the display panel provided in the embodiment of the disclosure, as shown in FIG. 1 and FIG. 3, the display panel includes a conventional display area A1, and the first color filter 51 located in the conventional display area A1 covers an area other than the gap between the second color filter 52 and the third color filter 53. In this way, on the one hand, it can avoid that the length of the gap between the second color filter 52 and the third color filter 53 cannot satisfy the filling of first color filter 51 when the first color filter 51 of the current high-resolution display panel is made. The first color filter 51 in the embodiment of the disclosure does not cover this gap, and the first color filter 51 can be avoided from overlapping with the second color filter 52 and the third color filter 53, so as to avoid the reflected stray light due to color separation in the dark state. On the other hand, the production area of the first color filter 51 can be improved, so that the hue of the display panel in the dark state is better.

In the specific embodiment, in the display panel provided in the embodiment of the disclosure, as shown in FIG. 1 and FIG. 3, each edge of the first color filter 51 located in the conventional display area A1 is concave toward the center of the polygon (first color filter 51). In this way, compared with each edge of the color filter in the conventional display panel is a straight line, the arc-shaped design of each edge in the embodiment of the disclosure can weaken the diffraction effect of the reflected light produced by the external ambient light after passing through the conventional display area A1 of the display panel, thereby weakening the phenomenon of color separation produced by the conventional display area A1.

In the specific embodiment, in the above-mentioned display panel provided in the embodiment of the disclosure, as shown in FIG. 1 and FIG. 3, the first color filter 51 located in the conventional display area A1 can be a central symmetrical figure. Of course, it is not limited to this, as long as the corners and edges of the first color filter 51 are circular.

In the specific embodiment, in order to adjust the ambient brightness of the display panel, in the display panel provided in the embodiment of the disclosure, as shown in FIG. 1 and FIG. 4, the display panel further includes a light-transmitting display area A2, and the light-transmitting display area A2 is close to the edge of the display panel. The first color filter 51 located in the light-transmitting display area A2 covers at least a part of the area between the adjacent second color filters 52 except the gap between the second color filter 52 and the third color filter 53.

As shown in FIG. 4, the light-transmitting display area A2 includes a plurality of light-transmitting holes V. The light-transmitting holes V are located in the area of the gap between the adjacent second color filters 52 that is not covered by the first color filter 51. Because the pixel defining layer 2 and the black matrix layer 4 cannot transmit light, a hole can be made on the pixel definition layer 2 and the black matrix layer 4 in the area of the gap between the adjacent second color filters that is not covered by the first color filter, so as to realize the light transmission in a hole area.

Optionally, the light-transmitting display area A2 may be located inside the conventional display area A1, for example, the light-transmitting display area A2 may be located in the upper left corner or the upper right corner of the display panel. The embodiment of the disclosure takes the light-transmitting display area A2 located in the left corner of the display panel as an example. The size of the opening of the light-transmitting display area A2 can vary from several millimeters.

Specifically, an ambient light adjustment sensor is generally arranged on the back of the display panel corresponding to the light-transmitting display area A2 to adjust the ambient light brightness of the display panel and improve the display effect.

In the specific embodiment, in the above-mentioned display panel provided in the embodiment of the disclosure, as shown in FIG. 4, only six edges of the first color filter 51 located in the light-transmitting display area A2 are concave toward the center of the polygon. In order to further weaken the phenomenon of color separation, in the specific embodiment, in the above-mentioned display panel provided in the embodiment of the disclosure, as shown in FIG. 7, FIG. 7 is an enlarged view of the light-transmitting display area A2 in FIG. 1, and each edge of the first color filter 51 located in the light-transmitting display area A2 is concave toward the center of the polygon. In this way, the diffraction effect of the reflected light generated by the external ambient light through the light-transmitting display area A2 of the display panel can be weakened, so as to weaken the phenomenon of color separation in the light-transmitting display area A2.

In the specific embodiment, in the display panel provided in the embodiment of the disclosure, as shown in FIG. 7, the surface of the concave part (the edge of the first color filter 51) corresponding to the light-transmitting hole V is a third circular arc. The shape of the light-transmitting hole V may be a special-shaped polygon, and the figure of the light-transmitting hole V is roughly complementary to the figure of the adjacent concave part. In this way, the design of the light-transmitting hole V with special-shaped polygon structure can increase the area of the light-transmitting hole V, thereby increasing the transmittance of the light-transmitting display area A2 and improving the sensitivity of the ambient light adjustment sensor.

Optionally, the shape of the light-transmitting hole V can be a special-shaped pentagon, a special-shaped heptagon, a special-shaped decagon, etc., and is not limited here. The embodiment of the disclosure takes that the light-transmitting display area A2 includes the light-transmitting holes V of different shapes as an example. Of course, the shape of each light-transmitting hole V can be the same, which can be manufactured according to the actual situation. The area of the light-transmitting hole V can be maximized as much as possible, so as to improve the transmittance of the light-transmitting display area A2.

Specifically, FIG. 4 only illustrates the schematic layout diagram of the pixel definition layer, the black matrix layer and the color filter layer in the repeated 4*4 pixel units in the light-transmitting display area A2, and is different from the conventional display area A1 in that in the light-transmitting display area A2, the pixel definition layer 2 and the black matrix layer 4 needs to be provided with holes to ensure the transmittance of ambient light (such as 550 nm) and ensure the recognition performance of the ambient light adjustment sensor. The light-transmitting hole V is positioned between the adjacent second color filters 52, and in the thickness direction of the display panel, the light-transmitting hole V is the sleeve hole structure that passes through the pixel definition layer and the black matrix layer, so that each pixel unit (including a red subpixel R, a green subpixel G, a blue subpixel B) can have a light-transmitting hole V. Meanwhile, in order to ensure that the aperture ratio is maximized, an area of the pixel circuit of the subpixel can be reduced, and the light-transmitting hole V can be designed with special-shaped polygons.

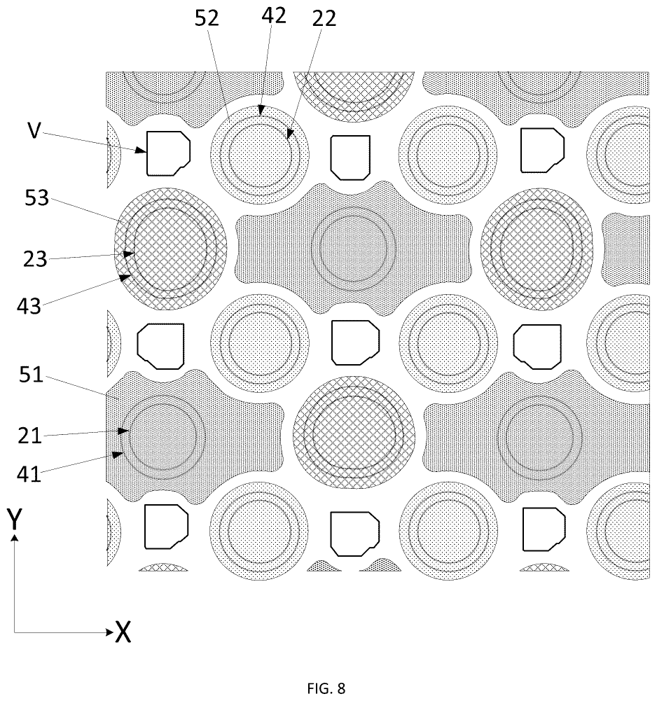

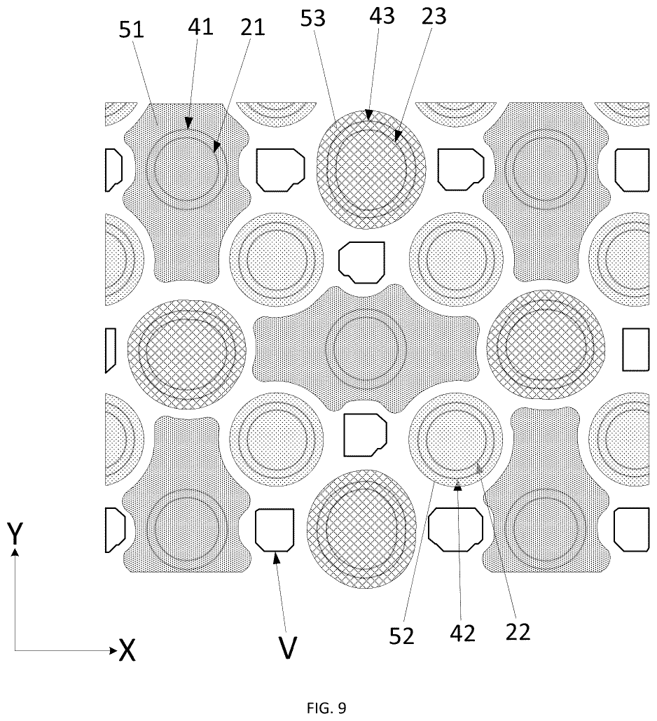

In the specific embodiment, in the above-mentioned display panel provided in the embodiment of the disclosure, as shown in FIG. 1 and FIG. 7 to FIG. 9, FIG. 8 and FIG. 9 are respectively two partially enlarged views of the light-transmitting display area A2 in FIG. 1.

As shown in FIG. 7, in the light-transmitting display area A2, each first color filter 51 includes a long axis extending along the first direction Y and a short axis extending along the second direction X, and the light-transmitting holes V are arranged at two ends of the short axis. The first direction Y intersects the second direction X.

Alternatively, as shown in FIG. 8, in the light-transmitting display area A2, each first color filter 51 includes a short axis extending along the first direction Y and a long axis extending along the second direction X, and the light-transmitting holes V are arranged at two ends of the short axis.

Alternatively, as shown in FIG. 9, in the light-transmitting display area A2, a part of the first color filters 51 include a long axis extending along the first direction Y and a short axis extending along the second direction X, and the other part of the first color filters 51 include a short axis extending along the first direction Y and a long axis extending along the second direction X. The light-transmitting holes V are arranged at two ends of the short axis. In this way, the number of light-transmitting holes V can be set as much as possible to further increase the transmittance of the light-transmitting display area A2.

In the specific embodiment, in the display panel provided in the embodiment of the disclosure, as shown in FIG. 1 and FIG. 7 to FIG. 9, the display panel includes a data line (not shown) and a gate line (not shown) that are crossed. For example, the gate line extends along the second direction X, and the data line extends along the first direction Y.

In the specific embodiment, in order to ensure the light transmittance of the light-transmitting hole, in the above-mentioned display panel provided in the present embodiment, as shown in 6, the width d4 of the gap between the light-transmitting hole V and the first color filter 51 is greater than or equal to 1 μm, and the width d5 of the gap between the light-transmitting hole V and the third color filter 53 is greater than or equal to 1 μm. This ensures that the color filter layer does not cover the light-transmitting hole V.

Optionally, the difference between the design values of d4 and d5 is mainly the difference of the CD Bias (Critical Dimension Bias) of the first color filter 51 and the third color filter 53. The CD Bias of the first color filter 51 refers to the deviation between the target size and the actual size of the first color file 51, and the CD Bias of the third color filter 53 refers to the deviation between the target size and the actual size of the third color filter 53. For example, the target values of d4 and d5 both can be 1.5 μm, so as to avoid the first color filter 51 and the third color filter 53 covering the light-transmitting hole V.

In the specific embodiment, in the above-mentioned display panel provided in the embodiment of the disclosure, as shown in FIG. 2 to FIG. 4, the area of the second opening (41, 42 and 43) is larger than the area of the first opening (21, 22 and 23), which increases the light extraction efficiency of the emergent light.

In the specific embodiment, in the above-mentioned display panel provided in the embodiment of the disclosure, as shown in FIG. 2 to FIG. 4, the area of the first color filter 51, the area of the second color filter 52 and the area of the third color filter 53 are respectively greater than the area of the second openings respectively corresponding to the first color filter 51, the second color filter 52 and the third color filter 53. For example, the area of the first color filter 51 is greater than the area of the second opening 41, the area of the second color filter 52 is greater than the area of the second opening 42, and the area of the third color filter 53 is greater than the area of the second opening 43, so that the display panel can weaken the phenomenon of color separation in the dark state to obtain a better hue.

In the specific embodiment, in the above-mentioned display panel provided in the embodiment of the disclosure, as shown in FIG. 3 and FIG. 4, the shape of the first opening (21, 22 and 23) may include a circle or an oval, and the shape of the second opening (41, 42 and 43) may include a circle or an oval.

In the specific embodiment, the display panel provided in the embodiment of the disclosure, as shown in FIG. 1, further includes an under-screen camera area A3. The under-screen camera area A3 is close to the edge of the display panel. Specifically, the under-screen camera area A3 can be located in the conventional display area A1, and the under-screen camera area A3 can be formed by digging holes in the conventional display area A1, so that photosensitive devices such as cameras can be arranged on the back of the under-screen camera area A3, and the narrow bezel design of the display panel can be realized.

Based on the same invention conception, an embodiment of the disclosure further provides a display device, including the display panel provided in the embodiment of the disclosure. The principle of solving the problem of the display device is similar to that of the aforesaid display panel, so the implementation of the display device can refer to the implementation of the aforementioned display panel, and will not be repeated here.

In the specific embodiment, the display device provided in the embodiment of the disclosure may be a full-screen display device, or may be a flexible display device, etc., and is not limited herein.

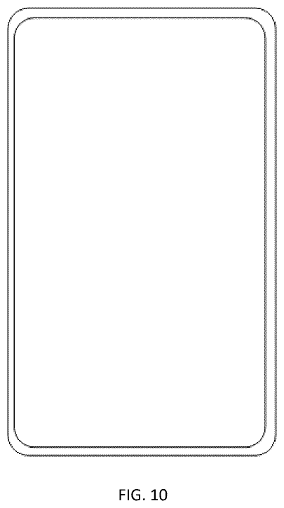

In the specific embodiment, the display device provided in the embodiment of the disclosure may be a full-screen mobile phone as shown in FIG. 10. Of course, the above-mentioned display device provided in the embodiment of the disclosure may be a tablet computer, a television, a monitor, a notebook computer, a digital photo frame, a navigation device, and any other product or component with a display function. The other necessary components of the display device should be included based on the understanding of those skilled in the art, which are not described herein and should not be used as a limitation on the disclosure.

The embodiment of the present disclosure provides a color filter arrangement structure, a display panel and a display device, by arranging first color filter, the second color filter and the third color filter which do not overlap with each other, and the first color filter covers the area between at least part of the adjacent second color filters except the gap between the second color filter and the third color filter, when the color filter arrangement structure is the color filter layer of the display panel of the high-resolution COE structure, the first color filter and the second color filter and the third color filter do not overlap with each other, and the area filled with the first color filter can be improved as much as possible, the hue of the product in the dark state can be optimized, the green reflected light can be reduced when the display panel is in the off state, allowing the screen to be closer to black, so that the problem that the screen cannot display a pure black picture in the dark state due to the hue deviation of the reflected light in the related art can be solved.

Although preferred embodiments of the disclosure have been described, those embodiments may make additional changes and modifications to these embodiments once they have knowledge of the basic concept of inventive step. Therefore, the attached claims are intended to be construed to include the preferred embodiment and all changes and modifications that fall within the scope of this disclosure.

Obviously, a person skilled in the art may make various changes and variants to the embodiments of the disclosure without departing from the spirit and scope of the embodiments of the disclosure. Thus, if these modifications and variants of the disclosure embodiments fall within the scope of the claims of the disclosure and their equivalents, the disclosure is also intended to include such modifications and variants.

1-30. (canceled)

31. A color filter arrangement structure, comprising:
a first color filter, a second color filter and a third color filter not overlapping with each other, wherein the first color filter covers an area between at least part of adjacent second color filters except a gap between the second color filter and the third color filter.

32. The color filter arrangement structure of claim 31, wherein a shape of the first color filter is a polygon, a corner of the polygon is a first circular arc that is convex to a side away from a center of the polygon, and at least one edge of the polygon is concave toward the center of the polygon.

33. The color filter arrangement structure of claim 32, wherein a shape of the second color filter comprises a circle or an oval, and a shape of the third color filter comprises a circle or an oval;
the second color filter and the third color filter are alternately arranged at a side of each edge of the first color filter.

34. The color filter arrangement structure of claim 33, wherein the color filter arrangement structure comprises a first area;
wherein each first color filter in the first area covers an area except the gap between the second color filter and the third color filter, and each edge of each first color filter in the first area is concave toward the center of the polygon.

35. The color filter arrangement structure of claim 34, wherein concave surfaces of the polygon corresponding to the second color filter and the third color filter are second circular arcs, a second circular arc corresponding to a second color filter is same as a shape of an edge of the second color filter adjacent to the second circular arc, and a second circular arc corresponding to a third color filter is same as a shape of an edge of the third color filter adjacent to the second circular arc.

36. The color filter arrangement structure of claim 34, wherein the color filter arrangement structure comprises a second area;
the second area comprises a plurality of light-transmitting holes, and the light-transmitting holes are located in areas of the gap between adjacent second color filters that is not covered by the first color filter.

37. The color filter arrangement structure of claim 36, wherein each edge of the first color filter in the second area is concave towards the center of the polygon, a concave surface of the polygon corresponding to the light-transmitting hole is a third circular arc, a shape of each light-transmitting hole is a special-shaped polygon, and a figure of the light-transmitting hole is roughly complementary to a figure of the concave surface adjacent to the each light-transmitting hole.

38. A display panel, comprising:
a base substrate;
a pixel defining layer at a side of the base substrate, wherein the pixel defining layer comprises a plurality of first openings;
an encapsulation layer at a side of the pixel defining layer away from the base substrate;
a black matrix layer at a side of the encapsulation layer away from the base substrate, wherein the black matrix layer comprises a plurality of second openings corresponding to the first openings in one-to-one manner;
a color filter layer at a side of the black matrix layer away from the base substrate, wherein the color filter layer comprises a first color filter, a second color filter and a third color filter corresponding to the second openings in one-to-one manner, and the first color filter, the second color filter and the third color filter do not overlap with each other;
wherein the first color filter covers an area between at least part of adjacent second color filters except a gap between the second color filter and the third color filter.

39. The display panel of claim 38, wherein an area of the first color filter is greater than an area of the third color filter, and the area of the third color filter is greater than an area of the second color filter.

40. The display panel of claim 39, wherein a periphery of the first color filter is provided with the second color filter and the third color filter arranged alternately around the first color filter.

41. The display panel of claim 40, wherein a shape of the second color filter comprises a circle or an oval, and a shape of the third color filter comprises a circle or an oval.

42. The display panel of claim 41, wherein a shape of the first color filter is a polygon, and the second color filter and the third color filter arranged alternately around the first color filter are respectively located at a side of each edge of the polygon;
wherein a corner of the polygon is a first circular arc that is convex to a side away from a center of the polygon.

43. The display panel of claim 42, wherein at least one edge of the polygon is concave toward the center of the polygon;
wherein concave surfaces corresponding to the second color filter and the third color filter are second circular arcs, a second circular arc corresponding to a second color filter is the same as a shape of an edge of the second color filter adjacent to the second circular arc, and a second circular arc corresponding to a third color filter is the same as a shape of an edge of the third color filter adjacent to the second circular arc.

44. The display panel of claim 42, further comprising a conventional display area, wherein a first color filter in the conventional display area covers an area except the gap between the second color filter and the third color filter;
wherein each edge of the first color filter in the conventional display area is concave toward the center of the polygon.

45. The display panel of claim 44, further comprising a light-transmitting display area;
wherein the light-transmitting display area comprises a plurality of light-transmitting holes, and the light-transmitting holes are located in an area not covered by the first color filter, of the gap between adjacent second color filters.

46. The display panel of claim 45, wherein each edge of the first color filter in the light-transmitting display area is concave toward the center of the polygon;
wherein a concave surface corresponding to the light-transmitting hole is a third circular arc, a shape of the light-transmitting hole is a special-shaped polygon, and a figure of the light-transmitting hole is roughly complementary to a figure of the concave surface adjacent to the light-transmitting hole.

47. The display panel of claim 45, wherein in the light-transmitting display area, the first color filter comprises a long axis extending along a first direction and a short axis extending along a second direction, and the light-transmitting holes are arranged at two ends of the short axis; wherein the first direction intersects the second direction;
or, in the light-transmitting display area, the first color filter comprises a short axis extending along a first direction and a long axis extending along a second direction, and the light-transmitting holes are arranged at two ends of the short axis;
or, in the light-transmitting display area, a part of the first color filters comprise a long axis extending along a first direction and a short axis extending along a second direction, the other part of the first color filters comprise a short axis extending along the first direction and a long axis extending along the second direction, and the light-transmitting holes are located at two ends of the short axis.

48. The display panel of claim 38, wherein an area of the second opening is greater than an area of the first opening; and/or
an area of the first color filter is greater than an area of a corresponding second opening, an area of the second color filter is greater than an area of a corresponding second opening, and an area of the third color filter is greater than an area of a corresponding second opening.

49. The display panel of claim 38, wherein the first color filter is a red color filter, the second color filter is a green color filter, and the third color filter is a blue color filter.

50. A display device, comprising the display panel of claim 38.
